(19) United States
(12) Patent Application Publication
(10) Pub. No.: US 2010/0155106 A1
(43) Pub. Date: Jun. 24, 2010

(54) METHOD AND APPARATUS FOR OPTICAL DIFFERENTIATION TO DETECT MISSING COMPONENTS ON A CIRCUIT BOARD

(75) Inventors: James David Britton, El Paso, TX (US); Thomas J. Pelc, Newark, CA (US); Jorge Eduardo Martinez-Vargas, JR., San Francisco, CA (US)

Correspondence Address: Dorsey & Whitney LLP;on behalf of Sun Microsystems, Inc., 370 Seventeenth Street, Republic Plaza Building, Suite 4700, Denver, CO, 80202-5647, US

(73) Assignee: Sun Microsystems, Inc., Santa Clara, CA (US)

(21) Appl. No.: 12/341,783

(22) Filed: Dec. 22, 2008

(51) Int. Cl. H05K 1/02; H05K 3/22

(52) U.S. Cl. 174/250; 29/829

(57) ABSTRACT

Implementations of the present invention may involve methods for providing an optical differentiation on a printed circuit board to assist in identifying a missing or improperly mounted component. The optical differentiation may be such that, when a component of the board is missing or improperly attached to the board, a distinct optical difference is created on the board in the visible or non-visible spectrum. Several implementations may create a visible color difference, a non-visible mark, a recognizable shape, texture change, cross hatching or other form of physical modification beneath the component or on the printed circuit board. Other implementations may include the optical differentiation within a silk-screen of the board or on an internal layer of the board.

### FIELD OF THE INVENTION

Aspects of the present disclosure relate to printed circuit boards and testing of the same. More particularly, aspects may involve a method and apparatus for intentionally differentiating a portion of a printed circuit board to create an optical indicator on the board when a component may be missing or improperly mounted on the board.

### BACKGROUND

Modern electronic assemblies are often examples of spectacular visual complexity. Printed circuit boards, for example, may include anywhere from a few surface-mounted components to tens of thousands of such components on a single board. Further, as the demand for smaller and smaller computing devices has increased, surface-mounted components on printed circuit boards have begun to decrease in size beyond that of normal human vision. For example, 0201-sized, or 20 thousandths of an inch long by 12 thousandths of an inch wide, surface-mount components are now commonplace on printed circuit boards of small computing devices, such as cell phones. Further, the next generation of printed circuit board components will be 01005-sized, or 16 thousandths of an inch long by 8 thousandths of an inch wide. Components of this size are no larger than a small grain of sand and may be very difficult to see with the naked eye.

The small size of these surface-mount components often makes it difficult to successfully populate a printed circuit board, particularly in mass-produced circuit boards. Because of tiny surface area of the circuit board components, there is less surface to attach the components to the board, causing the components to not properly mount on the circuit board. Thus, it is becoming increasingly common that the smaller components of the board fall off or are knocked off during population or post-population handling of the board. A missing component of a circuit board assembly may cause the board to operate incorrectly or may cause the board to fail completely, requiring the replacement of the board within the electronic device.

To detect when a component of a printed circuit board has fallen off the board or is otherwise missing, printed circuit board manufacturers have developed a few techniques to detect the missing components. In one example, an automated optical inspection (AOI) machine is used to visually inspect the populated circuit board during production of the board. The AOI machine may take a picture of a properly populated circuit board and compare that stored image to each populated circuit board coming off of an assembly line. If the images do not match, the AOI may determine where the images differ and alert a technician that the board may have a missing or improperly placed component, which either results in further manual examination or discarding of the board. However, AOI machines are imprecise, sometimes generating false positives or failing to identify missing components. Further, AOI machines are generally very expensive and, therefore, not economical for small-volume circuit board designs.

Another technique used by printed circuit board manufacturers to detect the missing components involves a visual inspection by an inspector using a template. In this technique, an inspector may place a template containing cutouts for each component over the populated circuit board and visually attempt to locate any missing components. However, this technique is prone to user error due to the very small nature of the components and user fatigue from visually inspection of such small and complex component layouts, oftening results in missing components not being noticed, especially as surface-mount components of printed circuit boards have gotten smaller in size. Thus, what is needed is a method for detecting missing components on a printed circuit board that increases the likelihood that the absence of the components will be recognized without incurring prohibitive costs to the detection technique.

### SUMMARY

One implementation may take the form of a printed circuit board. The printed circuit board may define a surface and include a plurality of components electrically connected. Each of the components may define a footprint having a dimension. The plurality of components may also be mounted on the surface. The printed circuit board may also include an optical differentiation indicator defined on the surface of the printed circuit board, with the optical differentiation indicator occupying substantially the same position on the surface of the printed circuit board and having substantially the same dimension as the component footprint.

Another implementation may take the form of a method for marking a printed circuit board. The method may comprise the operation of determining at least one location of a surface-mount component on the printed circuit board, with the surface-mount component defining a footprint having a dimension. The method may also include the operation of applying an optical differentiation mark to the surface of the printed circuit board in the at least one location, the optical differentiation mark occupying substantially the same position on the surface of the printed circuit board and having substantially the same dimension as the component footprint. The mark may be such that when the surface-mount component is applied to the printed circuit board, the optical differentiation mark is at least partially obscured from view.

Another implementation may take the form of a method marking a printed circuit board. The method may comprise the operation of determining at least one location of a surface-mount component on the printed circuit board, with the surface-mount component defining a footprint having a dimension. The method may also include the operation of altering an internal layer of the printed circuit board in the at least one location, wherein the alteration of the internal layer of the printed circuit board creates an optical differentiation mark. The optical differentiation mark occupy substantially the same position on the surface of the printed circuit board and having substantially the same dimension as the component footprint, such that when the surface-mount component is applied to the printed circuit board, the optical differentiation mark is at least partially obscured from view.

### BRIEF DESCRIPTION OF THE DRAWINGS

FIG. 1A is a diagram illustrating a printed circuit board including an optical differentiating color between the pads of the surface-mounted components.

FIG. 1B is a diagram illustrating a printed circuit board including an optical differentiating color between the pads of the surface-mounted components, with several surface-mounted components soldered to the circuit board.

FIG. 2 is a diagram illustrating a printed circuit board including optical differentiating shapes between the pads of the surface-mounted components.

FIG. 3 is a diagram illustrating a printed circuit board including optical differentiation between the pads of the surface-mounted components, including color, shape and texture differentiation.

FIG. 4 is a flowchart illustrating an implementation for creating an optical differentiation on a printed circuit.

FIG. 5 is a flowchart illustrating an embodiment for creating an optical differentiation on an internal layer of a printed circuit board.

### DETAILED DESCRIPTION

Implementations of the present invention may involve methods for providing an optical differentiation on a printed circuit board to assist in identifying a missing or improperly mounted component. The optical differentiation may be such that, when a component of the board is missing or improperly attached to the board, a distinct optical difference is created on the board in the visible or non-visible spectrum. Several implementations may create a visible color difference, a non-visible mark, a recognizable shape, texture change, cross hatching or other form of physical modification beneath the component or on the printed circuit board. Other implementations may include the optical differentiation within a silk-screen of the board or on an internal layer of the board.

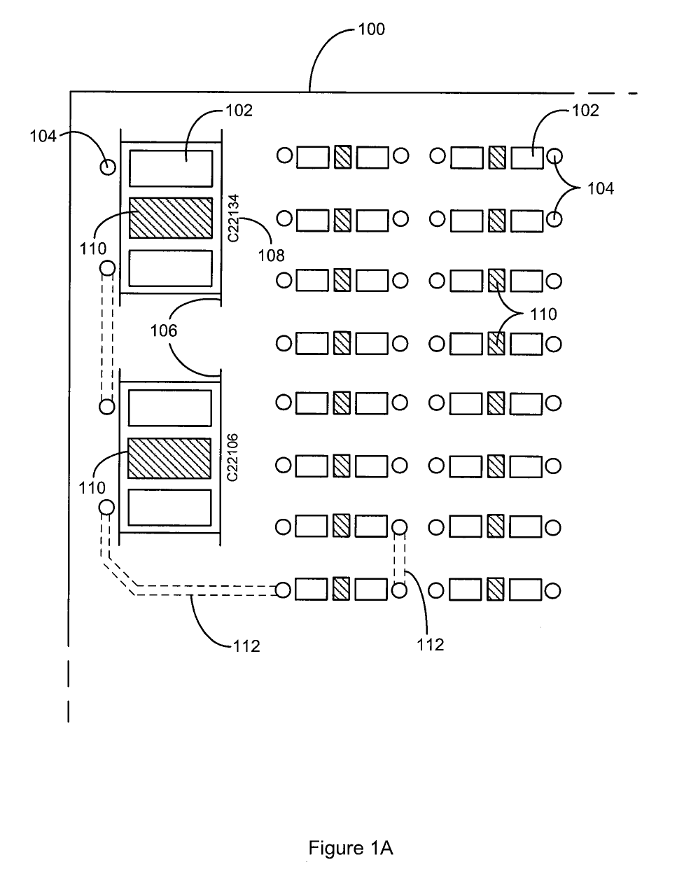

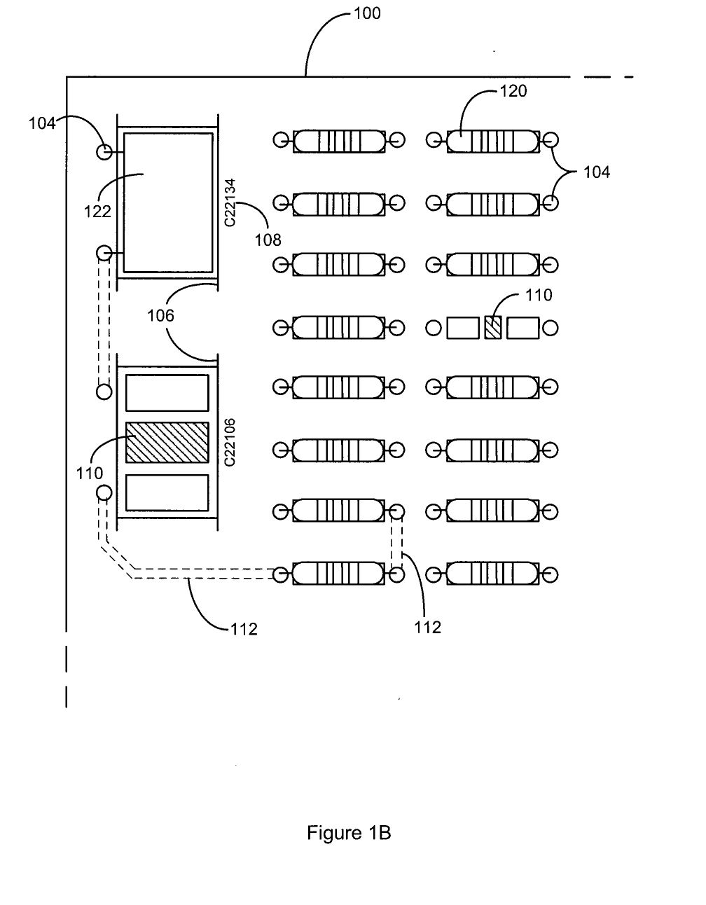

FIG. 1A is a diagram illustrating a printed circuit board 100 including an optical differentiating visible color or non-visible indicator 110 between the conductor pads 102 of the surface-mounted components. The differentiation indicator is denoted by a [symbol] pattern in FIG. 1A and FIG. 1B. However, it should be appreciated that the indicator may be a solid color or non-visible color and not a pattern at all. The differentiation indicator may be such that, when viewed during inspection of the board, the indicator 110 may be easily noticeable to the viewer and/or more predictably identified by an AOI machine. Further, the differentiation indicator may be located under one or several components of the circuit board such that the differentiation may be noticed when the component is missing or placed incorrectly on the board.

The printed circuit board (PCB) 100 of FIG. 1 may be composed of a layer of conductive material laminated onto a non-conductive substrate, while more advanced circuit boards may include several layers of conductive and non-conductive materials. FIG. 1 is a top view of a portion of a PCB, with the various possible conductive layers and the substrate are not visible on the top of the board. The layers of conductive material may include several conductive pathways etched into the conductive material providing the traces 112 for the circuit of the board. While a few traces 112 are shown in FIG. 1, the traces may provide pathways between some or all of the components of the PCB 100 on several layers of the PCB. Once the traces 112 of the circuit are created, one or more surface mounted components that comprise the circuit may be mounted on and electrically coupled to the printed circuit board 100 to create the functional printed circuit assembly. The surface mounted components may range from simple circuit components, such as resistors, capacitors and inductors, to more complex components, such as field programmable gate array (FPGA) chips or system-on-a-chip (SOC) multiprocessing chips. Generally, the surface mounted components may be any known or hereafter developed electrical component that may be mounted on a PCB.

The PCB 100 may also include conductor plates 102 located along the surface of the board. The conductor plates 102 may provide an area on the PCB 100 that the components of the circuit may be mounted to the board by soldering the component to the conductor plate. The PCB 100 may also include several vias 104 to electrically connect the components of the circuit to underlying traces of the PCB circuit. The vias 104 may form part of an electrical connection between the surface-mounted components of the PCB 100 with other components of the circuit or to a ground or power layer of the board. As shown in more detail in FIG. 1B, the components of the circuit may also be electrically connected and mounted to the PCB 100 through a solder connection at the vias 104.

To prevent the solder of the PCB 100 from bridging between two conductor plates 102 or vias 104, a solder resistant coating may be applied to the surface of the PCB. The solder resistant coating is often made from a polymer and is usually green in color, although the solder resistant coating may be any color. Printed on the solder resistant coating may be silk screen or screen print 106. The silk screen 106 may comprise line art or text printed on the outer surface of the PCB 100 to provide information about the circuit contained on the circuit board, such as component designators, switch settings, test points and other features helpful in providing information about the circuit. As shown in the PCB 100 of FIG. 1, the silk screen may include line art 106 providing an outline of an expected component and the component designation 108 positioned adjacent the location of a referenced component. This information may assist an assembler in placing the components on the PCB 100 or a tester in identifying certain components of the board circuit.

To assist in the detection of a missing component on the PCB 100, the visible color or non-visible differentiation indicator 110 may be applied to the PCB 100 underneath the expected placement of the surface-mounted components of the PCB such that the indicator be noticeable when the component is missing. One implementation may provide for a bright visible color 110 mark applied to the PCB 100 under the expected placement of the surface-mounted components. For example, the visible color differentiation 110, shown as a cross-hatch rectangle in FIGS. 1A and 1B may be placed between two conductor pads 102 of a component with the expectation that a component may be placed between the conductor pads 102, partially or completely obscuring the color differentiation 110. Further, the color of the visible differentiation 110 may be selected for maximum visibility based on the surrounding colors of the PCB 100. For example, if the solder resistance coating of the PCB 100 is dark green, than a bright or neon orange color may be selected as the visible differentiation. Alternatively, if the solder resistance coating of the PCB 100 is a lighter color, such as a yellow, a dark visible differentiation, such as a dark blue or green, may be used. Further, the color of the expected components to be placed on the PCB 100 may also be taken into consideration when choosing the visible color differentiation mark. For example, if the colors of the components of the board are generally a black or dark grey, a more colorful visible color may be selected, such as a pink or yellow. Generally, however, any visible color may be used as the optical differentiation beneath the surface-mounted components to indicate a missing or improperly mounted component.

As shown in FIG. 1A, the optical differentiation color 100 may be located between the conductor pads 102 of each surface-mount component on the PCB 100. The placement of the differentiation between the conductor pads 102 may facilitate the color being visible when the component is missing, but not-visible when the component is properly placed on the PCB 100. For example, a surface-mount component, such as a resistor, may be intended for the conductor pads 102 of a PCB 100. When properly mounted on the PCB 100, the resistor may cover the differentiation color 110 located between the two conductor pads 102 for that component when viewed from above. However, when the resistor is not properly installed or is missing, the differentiation color 110 may be visible from above. For example, FIG. 1B is a diagram illustrating a printed circuit board including an optical differentiating color between the pads of the surface-mounted components, with several surface-mounted components soldered to the circuit board. The PCB 100 of FIG. 1B includes the same features as that of FIG. 1A, including vias 104, traces 112 and silkscreen markings 108. However, the PCB 100 of FIG. 1B also includes several surface mounted components soldered to the board, including resistors 120 and capacitors 122. As shown, when the components are soldered to the board, the color indicators 110 may be obstructed from view. However, if a component is missing or improperly mounted on PCB 100, the color indicator 110 may be viewed by an inspector or inspecting machine. For example, in FIG. 1B, a resistor 120 and a capacitor 122 may be missing as the color indicators 110 below those components are visible.

In this manner, the differentiation color 110 may be visible to an inspector when a component is missing through a quick inspection of the PCB 100. Thus, if the inspector notices any of the differentiation color 110 on the board during inspection, the inspector may be made aware that a component may be missing or improperly mounted on the PCB. Alternatively, the indicator color may be such that it may be recognized by a machine. In this configuration, the color indicator may be chosen in accordance with an inspecting machine, such as an AOI. Thus, the inspecting machine may be programmed to recognize a particular color or invisible indicator and the differentiation indicator may be chosen accordingly such that the inspecting machine may recognize when a surface mount component is missing or improperly mounted.

It should be appreciated that the differentiation color 110 is not required to be located between the conductor pads 102 of a component. Rather, the differentiation color 110 may be located anywhere on the PCB 100 that may assist in detecting a missing or improperly mounted component. For example, some surface mount components may cover an area of the PCB larger than the area between the conductor pads 102. Thus, the differentiation indicator may be located beneath the surface mount component to indicate when the component is missing, without the necessity of the mark being between the conductor pads 102. Further, it should be appreciated that the differentiation color may take any shape and may not necessarily be located under each component of the PCB 100. Rather, an implementation may locate the differentiation color 110 under particular components, such as those that are extremely small or important to the overall performance of the PCB 100 assembly. Further, a color scheme may be employed to both help identify missing components as well as the type of component. For example, resistors may be associated with an orange mark whereas capacitors may be associated with a blue mark. Besides identifying a missing component, a technician, through color mapping to certain components or steps in the PCB assembly process, may be able to identify and isolate certain steps in the assembly process there are repeatedly failing. For example, a PCB may be populated by area. Each area may be matched with a particular color, such as a red color for the first area of the board that is populated. Thus, an inspector or inspecting machine may identify which step in the population process has improperly mounted components, such that a technician may diagnose which step in the population process to fix.

Similar implementations may locate an illuminable or less bright optical differentiation 110 on the PCB 100 to aid in detecting missing components. For example, one implementation may place an illuminable or less bright mark 110 underneath the surface-mounted components of the board that may be illuminated or glow when a ultra-violet (UV) light is shown on the mark. Thus, a populated PCB 100 may be placed under a UV light to detect any missing components on the board. If any of the components of the board are missing, the differentiation marks 110 may glow when placed under the UV light and hence be easily viewable and noticeable to an inspector, thereby indicating that a component or components are missing. Other implementations may use infra-red (IR) or other non-visible wavelength differentiations 110 that may be illuminated under particular circumstances or lights. Generally, any illuminable mark may be used that may differentiate the mark from the other areas of the PCB when viewed under particular circumstances, such as a UV or similar light. Further, similar to the visible differentiation, the illuminable differentiation 110 may be located between the conductor pads 102 or otherwise beneath a component along to aid in detecting a missing or improperly mounted component.

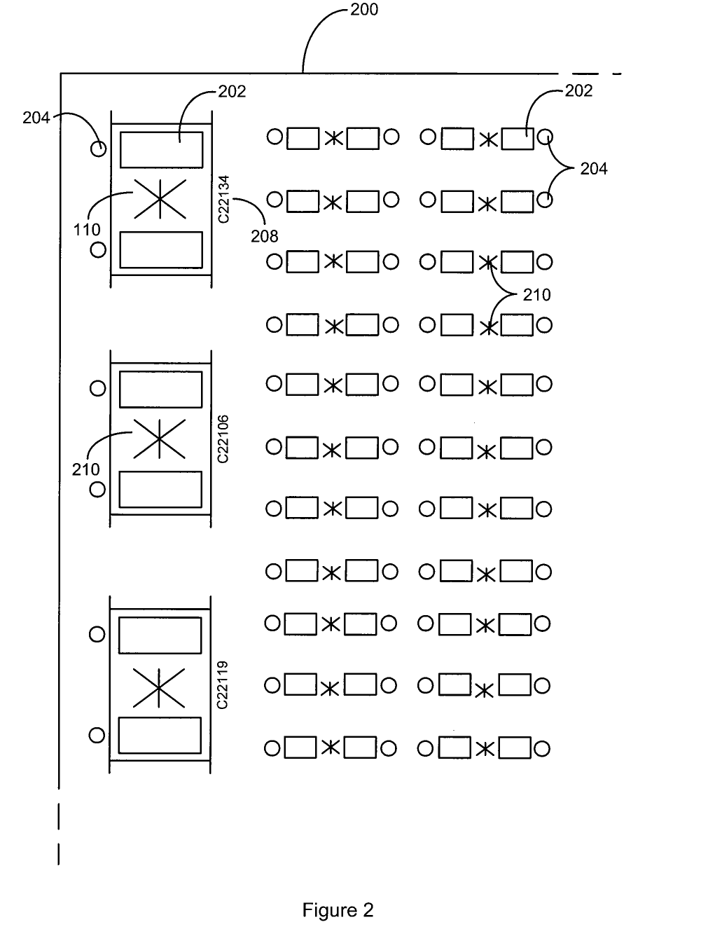

FIG. 2 is a diagram illustrating a printed circuit board including optical differentiating shapes between the pads of the surface-mounted components. In this implementation, the optical differentiation shapes may assist in detecting a missing surface-mounted component on the PCB.

Similar to the implementation shown in FIG. 1, the implementation of FIG. 2 may also include a PCB 200 with conductor pads 202 and vias 204. However, instead of a visible color or non-visible indicator located on the surface of the PCB 200, this implementation may include a noticeable shape 210 that may be recognized by an inspector or inspecting device of the PCB. For example, the PCB 200 may include a shape similar to an asterisk 210 located between the conductor pads 202 of the PCB 200. The unique shape 210 may assist in detecting a missing component in a similar manner as described above. Namely, the shape 210 may be visible from above when a component of the PCB 200 is missing or improperly attached to the board. While the placement of the shape 210 between the conductor pads 202 may facilitate the shape being visible only when the component is missing, it should be appreciated that the shape may be placed anywhere underneath a component on the PCB 200 that assists in the detection of a missing component. Also, while an asterisk shape is shown in FIG. 2, it should be appreciated that the shape 210 may be any unique shape that may differentiate the shape from the rest of the PCB 200 to indicate when a component of the PCB is missing.

In one implementation, the shape 210 may be a part of the silk screen applied to the PCB 200 during assembly of the PCB. As described above, a silk screen may be printed on the solder resistant coating of the PCB 200 and may comprise line art 206 or printed text 208. Further, a differentiation shape 210 may also be included in the silk screen effect applied to the PCB 200. For example, the asterisk 210 of FIG. 2 may be included on the PCB 200 as part of the silk screen process during assembly of the PCB. Thus, each differentiation shape 210 may be included on the board as part of the manufacturing process, at the same time that the other silk screen 206 writings are imprinted on the PCB 200 surface.

In another implementation, the differentiation shape 210 may also include aspects of a visible color or non-visible indicator as described above with reference to FIGS. 1A and 1B. For example, the asterisk shape 210 of FIG. 2 may be a visible color, such as bright or neon yellow as described above. In another implementation, the asterisk may be comprised from an illuminable differentiation indicator, such as a less-bright mark that glows or illuminates under a UV-light. Thus, the features of the visible or illuminable differentiation described above may be incorporated into the shape 210 of FIG. 2 to provide a noticeable optical differentiation to assist in detecting a missing or improperly mounted PCB component.

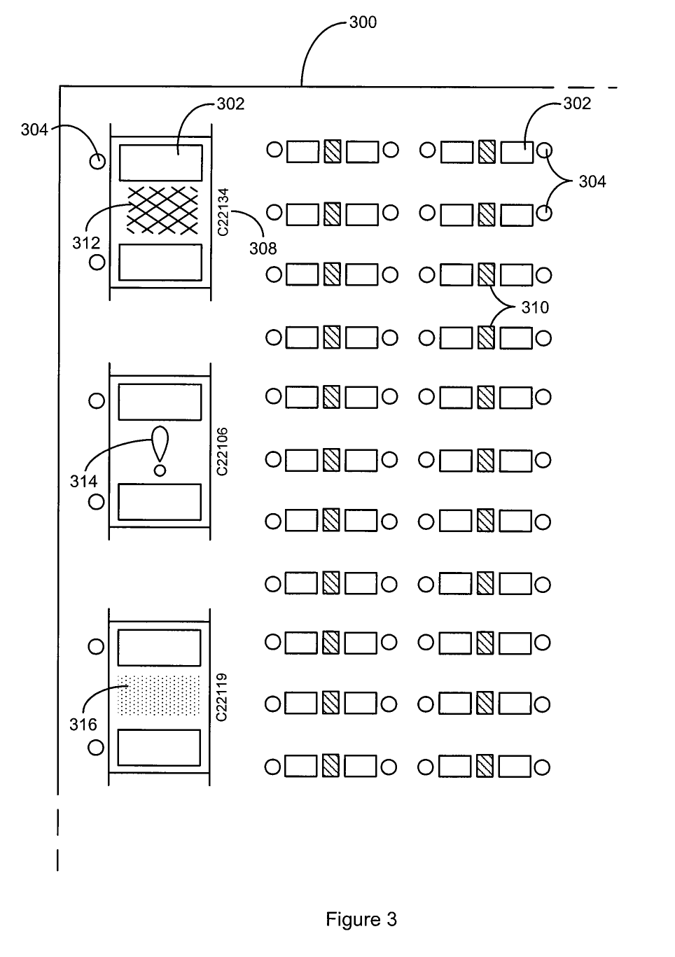

FIG. 3 is a diagram illustrating a printed circuit board including several optical differentiation techniques between the pads of the surface-mounted components, including color, shape and texture differentiation. As with the implementations of FIGS. 1A, 1B and 2, this implementation may also assist in determining if a surface-mounted component of a PCB is missing or improperly mounted on the board. However, this implementation may utilize several optical differentiation methods to aid in detecting missing components of the board.

The implementation of FIG. 3 may include both visible color or non-visible markings 310 and recognizable shapes 314 as described above with reference to FIGS. 1 and 2. Further, as shown, the visible or non-visible markings 310 and shapes 314 may both be included on a single PCB 300. For example, visible color differentiations 310 may be utilized to detect a missing resistor while a shape differentiation 314 may be used to detect a missing capacitor. Other optical differentiation techniques may also be included on the PCB 300 in a similar manner as discussed above to aid in detecting missing or improperly mounted components.

For example, PCB 300 may include a section including a cross-hatch image 312. The cross-hatch image 312 may be included on the PCB 300 in a similar manner as the shapes of FIG. 2. Namely, the cross-hatch may be a part of the silk screen printing 316 on the PCB 300 or may be a visible color or non-visible indicator. Further, the cross-hatch pattern may be located between the conductor pads 302 of a component such that the pattern may be visible when the component is missing. Generally, any marking pattern 312 that distinguishes the area from the rest of the PCB surface may be used to indicate that a component may be missing.

In another example, the PCB 300 underneath a component may have a different texture 316 than that of the PCB surface. For example, the area under the component may be a series of raised bumps 316, while the surface of the PCB 300 may be relatively smooth in comparison. When a component is missing or improperly mounted on the PCB, the differentiating texture 316 may be detected through a visual or tactile inspection of the PCB surface. Thus, the detection of the differentiation texture 316 may indicate that the component may be missing.

Thus, as shown in FIG. 3, a PCB may include several optical differentiation techniques to indicate that a surface-mounted component is missing. These techniques may be used for all or some of the components of the board. Further, each technique may be selected for optimal detection when the component is missing, depending on the component and size of the differentiation area. Generally, any technique may be used in combination with any other technique on the populated PCB 300 to aid in the detection of a missing component.

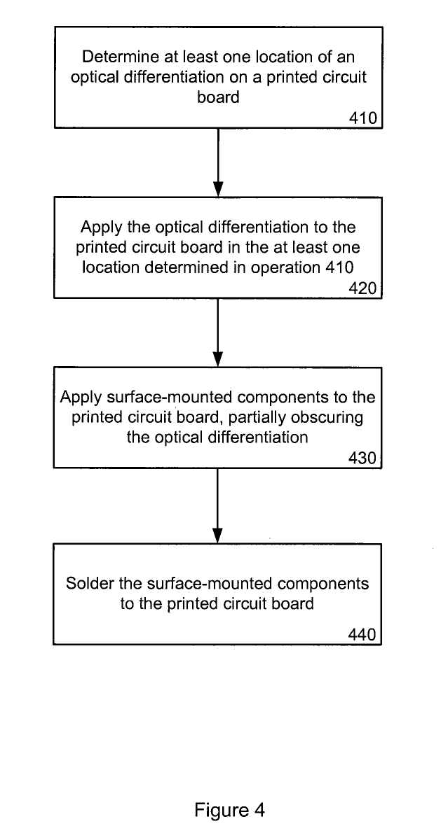

FIG. 4 is a flowchart illustrating an implementation for including an optical differentiation on a printed circuit. The optical differentiation may be applied to the PCB during manufacture of the board or during the process of populating the board with the surface-mounted components of the PCB circuit. Further, any optical differentiation technique discussed above may be utilized in connection with the implementation.

The implementation may begin in operation 410 by determining at least one location for an optical differentiation on a printed circuit board. As mentioned above, the optical differentiation may be located anywhere on the surface of the PCB such that the differentiation is partially obscured by a properly mounted component of the board. Generally, the optical differentiation may be located on the PCB underneath the surface-mounted components, such that when the component is missing or improperly mounted on the board, the optical differentiation may be viewed.

In operation 420, the optical differentiation may be applied to the PCB in at least the location determined in operation 410. The nature of the application of the optical differentiation to the PCB may vary with the differentiation technique used. For example, a visible color differentiation may be applied to the PCB through the application of a colorful ink or paint to the determined location. The differentiation may also be accomplished through the application of a colorful adhesive sticker stuck to the board in the determined location. Alternatively, the color differentiation color may be achieved through a color-changing solder-resistant coating applied to the PCB. The color-changing coating may be configured such that when the coating comes into contact with a particular chemical, the coating may change colors in the areas where the chemical is applied. For example, a portion of a green solder-resistant coating may turn bright orange when a chemical is applied to the portion. Thus, in this example, the implementation may apply the chemical to the coating in the determined locations to create a visible color differentiation underneath the components of the PCB or where the differentiation color may assist in detecting a missing component. Similarly, an illuminable differentiation mark may be applied to the determined locations, however the mark may not be visible until the PCB is put under a particular light, such as a UV light.

The application of a shape-specific differentiation technique may utilize the application techniques described above with reference to the visible color mark or may be applied during the silk screen process of the PCB. As explained, a silk screen may be printing on the surface of the PCB and may comprise line art or text. Further, the silk screen may be configured to also provide a shape or pattern optical differentiation to the PCB in the determined locations. Thus, when the silk screen is applied to the PCB during the manufacturing of the board, the optical differentiations may also be applied to the board in a similar color and style of the silk screen. Alternatively, the shapes may be applied using a colorful ink or paint, as described above.

Once the optical differentiations are applied to the PCB, the surface-mounted components of the PCB assembly may be placed on the board in operation 430. Generally, the components may be placed on conductor pads located on the surface of the PCB. Further, the optical differentiations may generally be placed between the conductor pads of the component such that, when the component is placed on the board, the component may partially or completely obscure the differentiation from sight. Thus, when the component is properly placed on the board, the optical differentiation may be hidden from view, visible only when the component is missing or improperly mounted on the board. Once the components are placed on the board, the components may be soldered to the PCB in operation 440 such that the PCB circuit may operate properly.

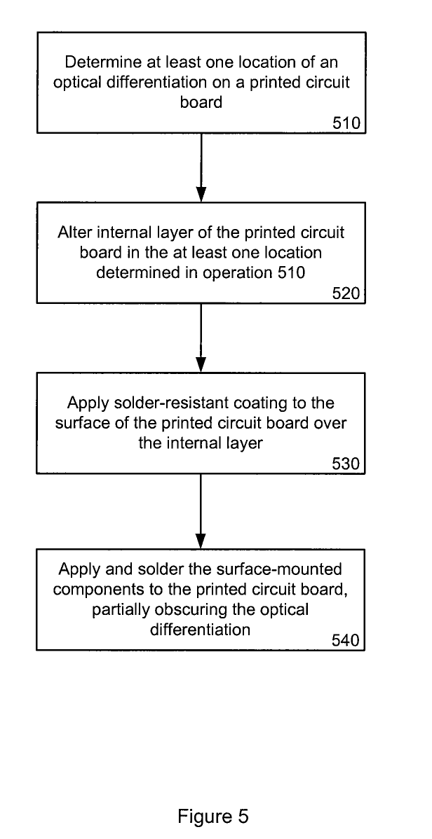

FIG. 5 is a flowchart illustrating an embodiment for creating an optical differentiation on an internal layer of a printed circuit board. The optical differentiation may be applied to the PCB during manufacture of the board, generally before the population of the PCB with the components of the circuit assembly. Further, many of the optical differentiation technique discussed above may be utilized in connection with this implementation.

The implementation may begin in operation 510 by determining at least one location for an optical differentiation on a printed circuit board. This operation may be similar to operation 410 of FIG. 4. Thus, the optical differentiation may be located anywhere on the surface of the PCB such that the differentiation is partially obscured by a properly mounted component of the board.

In operation 520, the optical differentiation may be applied to the PCB in at least the location determined in operation 510. However, in this implementation, the optical differentiation may be applied to the PCB by altering an internal layer of the PCB. For example, the PCB may include a layer comprised of fiberglass or other substance that supplies structure and rigidity to the board. Generally, the fiberglass layer may also act as the substrate on which the traces of the PCB circuit are applied. The optical differentiation techniques described above may also be applied to the fiberglass layer during construction of the board.

For example, a visible or non-visible differentiation mark as described above may be applied to the fiberglass or other internal layer. The application of the mark to the internal layer may be similar to the application of the mark to the outer layer of the PCB. However, in this implementation, the application of the mark may be applied to the internal layer, rather than on the outer layer of the PCB. Thus, the mark may be below the solder-resistant coating applied to the PCB, but still visible to an inspector or inspecting device. Similar visual techniques, such as a shape or pattern differentiation mark, may also be applied to the internal layers of the PCB such that the marks may be visible when the assembled PCB is viewed.

In another example, the internal layer may be physically altered to provide the optical differentiation. As described above with reference to FIG. 3, one possible optical differentiation may provide a different texture mark when compared to the surface of the PCB. For example, a series of bumps may be utilized as the optical differentiation for a particular component of the PCB. This differentiation may also be applied to the internal layer of the PCB. For example, the fiberglass layer of the PCB may be physically altered by providing a series of bumps in the determined location. Thus, when the PCB is assembled, the bumps of the internal layer may be felt or seen through the solder-resistant coating when a component of the PCB is missing. The change in texture of the internal layer may act as an optical differentiation for the implementations described herein.

Once the optical differentiations are applied to the internal layer, a solder-resistant coating may be cover the internal layer to protect the board from solder bridging conductors in operation 530. The coating may also cover the optical differentiation marks applied to the internal layer. Once the solder-resistant coating is applied, the surface-mounted components of the PCB assembly may be placed on the board and soldered into place in operation 540. Generally, when the components are placed on the board, the components may partially or completely obscure the optical differentiation of the internal layer.

It should be noted that the flowcharts of FIGS. 4 and 5 are illustrative only. Alternative embodiments of the present invention may add operations, omit operations, or change the order of operations without affecting the spirit and scope of the present invention.

The foregoing merely illustrates the principles of the invention. Various modifications and alterations to the described embodiments will be apparent to those skilled in the art in view of the teachings herein. It will thus be appreciated that those skilled in the art will be able to devise numerous systems, arrangements and methods which, although not explicitly shown or described herein, embody the principles of the invention and are thus within the spirit and scope of the present invention. From the above description and drawings, it will be understood by those of ordinary skill in the art that the particular embodiments shown and described are for purposes of illustrations only and are not intended to limit the scope of the present invention. References to details of particular embodiments are not intended to limit the scope of the invention.

What is claimed is:

1. A printed circuit board comprising:
a printed circuit board defining a surface and including a plurality of components electrically connected, each component defining a footprint having a dimension, the plurality of components mounted on the surface; and
an optical differentiation indicator defined on the surface of the printed circuit board, the optical differentiation indicator occupying substantially the same position on the surface of the printed circuit board and having substantially the same dimension as the component footprint.

2. The printed circuit board of claim 1 wherein the optical differentiation indicator comprises a brightly colored mark, wherein the color of the indicator is distinguishable from that of the color of the rest of the surface of the printed circuit board.

3. The printed circuit board of claim 1 wherein the optical differentiation indicator comprises an illuminable mark, wherein the mark may illuminate when an ultra-violet or infra-red light is shown on mark.

4. The printed circuit board of claim 1 wherein the optical differentiation indicator comprises a particular shape.

5. The printed circuit board of claim 1 wherein the optical differentiation indicator comprises a cross-hatch pattern.

6. The printed circuit board of claim 1 wherein the optical differentiation indicator comprises a texture difference from the surface of the printed circuit board.

7. The printed circuit board of claim 4 wherein the noticeable shape is applied to the printed circuit board during a silk screen process.

8. A method for marking a printed circuit board comprising:
determining at least one location of a surface-mount component on the printed circuit board, the surface-mount component defining a footprint having a dimension;
applying an optical differentiation mark to the surface of the printed circuit board in the at least one location, the optical differentiation mark occupying substantially the same position on the surface of the printed circuit board and having substantially the same dimension as the component footprint, such that when the surface-mount component is applied to the printed circuit board, the optical differentiation mark is at least partially obscured from view.

9. The method of claim 8 further comprising:
soldering the surface-mount component to the printed circuit board in the at least one location; and
visually inspecting the printed circuit board for the optical differentiation mark.

10. The method of claim 8 wherein the optical differentiation mark comprises a brightly colored mark, wherein the color of the mark is distinguishable from that of the color of the rest of the surface of the printed circuit board.

11. The method of claim 8 wherein the optical differentiation mark comprises an illuminable mark, wherein the mark may illuminate when an ultra-violet or infra-red light is shown on mark.

12. The method of claim 8 wherein the optical differentiation mark comprises a particular shape.

13. The method of claim 8 wherein the optical differentiation mark comprises a cross-hatch pattern.

14. The method of claim 8 wherein the applying operation further comprises printing the optical differentiation mark on the printed circuit board during a silk screen process.

15. A method marking a printed circuit board comprising:
determining at least one location of a surface-mount component on the printed circuit board, the surface-mount component defining a footprint having a dimension;
altering an internal layer of the printed circuit board in the at least one location, wherein the alteration of the internal layer of the printed circuit board creates an optical differentiation mark, the optical differentiation mark occupying substantially the same position on the surface of the printed circuit board and having substantially the same dimension as the component footprint, such that when the surface-mount component is applied to the printed circuit board, the optical differentiation mark is at least partially obscured from view.

16. The method of claim 15 further comprising:
applying a solder-resistant coating to the internal layer of the printed circuit board;
soldering the surface-mount component to the printed circuit board in the at least one location; and
visually inspecting the printed circuit board for the optical differentiation mark.

17. The method of claim 15 wherein the optical differentiation mark comprises a brightly colored mark, wherein the color of the mark is distinguishable from that of the color of the rest of the surface of the printed circuit board.

18. The method of claim 15 wherein the optical differentiation mark comprises a particular shape.

19. The method of claim 15 wherein the optical differentiation mark comprises a cross-hatch pattern.

20. The method of claim 15 wherein the optical differentiation mark comprises a texture difference from the surface of the printed circuit board.
